(19) United States
(12) Patent Application Publication
(10) Pub. No.: US 2026/0293289 A1
(43) Pub. Date: Sep. 24, 2026

(54) SEMICONDUCTOR DEVICE

(71) Applicant: Minebea Power Semiconductor Device Inc., Hitachi-shi, Ibaraki (JP)

(72) Inventor: Masaki SHIRAISHI, Hitachi-shi (JP)

(21) Appl. No.: 19/479,760

(22) PCT Filed: Feb. 1, 2024
(86) PCT No.: PCT/JP2024/003305

§ 371 Date: Oct. 29, 2025

(30) Foreign Application Priority Data
May 12, 2023 (JP) 2023-078956

(51) Int. Cl. H10D 84/00

(52) U.S. Cl. CPC H10D 84/161

(57) ABSTRACT

Examples effectively reduce a recovery loss of a diode region in an RC-IGBT. A semiconductor device has an IGBT region and a diode region in one chip. A first trench of the IGBT region and a second trench of the diode region are both wider trenches. The diode region includes: a first semiconductor layer of a second conductivity type provided on the upper surface side of the drift layer of a first conductivity type; and a second semiconductor layer of a first conductivity type and a carrier discharge layer of the second conductivity type are provided on the back surface side of the drift layer of the first conductivity type. The second semiconductor layer and the carrier discharge layer are alternately disposed.

### TECHNICAL FIELD

The present invention relates to a semiconductor device.

### BACKGROUND ART

An RC-IGBT (RC: Reverse-Conducting, reverse-conducting IGBT) that incorporates an IGBT (Insulated Gate Bipolar Transistor) and a diode in the same chip can share the termination region of the IGBT and the termination region of the diode, and thus has a merit of enabling chip size reduction. In addition, since the timing at which the IGBT is operated and the timing at which the diode is operated are respectively different, heat due to a loss that is caused in one of an IGBT region and a diode region can be distributed to the other, and be dissipated in the entire chip, so that there is also a merit of being capable of reducing heat resistance.

On the other hand, since the IGBT and the diode are made into the same chip, the simultaneous optimization of the respective elements is difficult, so that there is a problem that in particular, the lifetime control of the diode region is difficult.

In the diode region, a hole is injected from the p layer on the front surface at the time of diode conduction, and is accumulated, and a recovery current is generated at the time of diode recovery to cause a loss. Here, as the hole accumulation amount is larger, the recovery current is larger, so that to reduce the recovery loss, the hole injection reduction (lowered injection) is necessary.

As a technique for reducing the recovery loss of the diode region of the RC-IGBT, for example, there are Patent Literatures 1 and 2.

FIG. 12 of Patent Literature 1 illustrates the configuration of a semiconductor device in which a plurality of first grooves 6 (trenches) are provided in a region A (IGBT region), these grooves are provided to be equally spaced at a first spacing, a plurality of second grooves 10 (trenches) are provided in a region B (diode region), these grooves are provided to be equally spaced at a second spacing, and the second spacing is made smaller than the first spacing. According to the configuration of Patent Literature 1, since a larger number of grooves are provided in the region B (diode region), the area of a P base layer 2 contributing as the anode of the diode is relatively reduced when the diode is turned on, so that the hole injection from the P base layer 2 can be suppressed, the carrier density near the first main surface can be reduced, and the peak current at the time of the recovery operation can be lowered, thereby being capable of improving the recovery characteristic of the diode.

In addition, FIG. 10 of Patent Literature 2 illustrates the configuration of a semiconductor device that has an n+ type cathode layer 26 and a p+ type carrier discharge layer 27 on the back surface side of a diode region 20, has a p− type anode layer 55 having a lower p type impurity density than a p type anode layer 25 of the diode region 20 on the front surface side of a boundary region 50 between an IGBT region 10 and the diode region 20, and has a p type collector layer 56 on the back surface side of the boundary region 50. According to the configuration of Patent Literature 2, a hole injected from the p type anode layer 25 on the first main surface side at the time of the operation of the diode in the forward direction can be discharged via the p+ type carrier discharge layer 27, and the hole accumulation amount in an n− type drift layer 1 can be suppressed, so that the recovery loss can be reduced at the time of the recovery operation (see paragraph 0101). In addition, at the time of the operation of the diode in the forward direction, the hole injection from the p-type anode layer 55 having a low p type impurity density of the boundary region 50 is less, and the hole flow into the diode region 20 is also suppressed, so that the recovery loss can be reduced (see paragraph 0102).

### CITATION LIST

### Patent Literature

Patent Literature 1: Japanese Unexamined Patent Application Publication No. 2008-53648

Patent Literature 2: Japanese Unexamined Patent Application Publication No. 2022-15861

### SUMMARY OF INVENTION

### Technical Problem

However, although in Patent Literature 1, the hole injection is suppressed by reducing the area of the P base layer 2 of the diode portion of the RC-IGBT, the method of Patent Literature 1 reduces the area of the P base layer 2 by making the trench spacing small, thereby limiting, due to the limit of the trench processing, the reduction in the area of the P base layer 2.

In addition, in Patent Literature 2, the hole can be discharged via the p+ type carrier discharge layer 27, but although the structure on the front surface side is partitioned by the trenches, the p type anode layer 25 is present substantially on the entire surface, and the hole injection amount from the front surface side is thus increased, so that the suppression of the hole accumulation amount to reduce the recovery loss is limited.

To solve the problems, an object of the present invention is to provide a semiconductor device that can effectively reduce the recovery loss of a diode region in an RC-IGBT.

### Solution to Problem

To solve the above problems, a semiconductor device of the present invention has an IGBT region and a diode region in one chip. An IGBT of the IGBT region has a drift layer of a first conductivity type, a first body layer and a second body layer of a second conductivity type provided closer to a front surface side than the drift layer, an emitter layer of a first conductivity type provided closer to a front surface side than the first body layer and the second body layer, a collector layer of a second conductivity type provided closer to a back surface side than the drift layer, and a first trench provided between the first body layer and the second body layer. The first trench has a first gate electrode provided via a gate insulation film on the side wall on the first body layer side, a second gate electrode provided via the gate insulation film on the side wall on the second body layer side, and an in-trench insulation film, and the first gate electrode and the second gate electrode are spaced via the in-trench insulation film between the first gate electrode and the second gate electrode. A diode of the diode region has the drift layer, a primary first semiconductor layer and a secondary first semiconductor layer of a second conductivity type provided closer to a front surface side than the drift layer, a second semiconductor layer of a first conductivity type provided closer to a back surface side than the drift layer, and a second trench provided between the primary first semiconductor layer and the secondary first semiconductor layer. The second trench has a first diode region trench electrode formed via a diode region trench insulation film on the side wall on the primary first semiconductor layer side, a second diode region trench electrode formed via the diode region trench insulation film on the side wall on the secondary first semiconductor layer side, and the in-trench insulation film, and the first diode region trench electrode and the second diode region trench electrode are spaced via the in-trench insulation film between the first diode region trench electrode and the second diode region trench electrode. The diode region has a carrier discharge layer of a second conductivity type provided closer to a back surface side than the drift layer, and the second semiconductor layer and the carrier discharge layer are alternately disposed.

### Advantageous Effects of Invention

According to the semiconductor device of the present invention, the recovery loss of the diode region in the RC-IGBT can be effectively reduced.

It should be noted that problems, configurations, and effects other than the above will be apparent from the description of embodiments below.

### BRIEF DESCRIPTION OF DRAWINGS

FIG. 1 is a cross-sectional view of a semiconductor device of a first embodiment.

FIG. 2 is a cross-sectional view of a semiconductor device of a second embodiment.

### DESCRIPTION OF EMBODIMENTS

Hereinbelow, the embodiments of the present invention will be described with reference to the drawings. In the respective drawings and the respective embodiments, the same or similar components are indicated by the same reference numerals, and the overlapped description thereof is omitted.

### First Embodiment

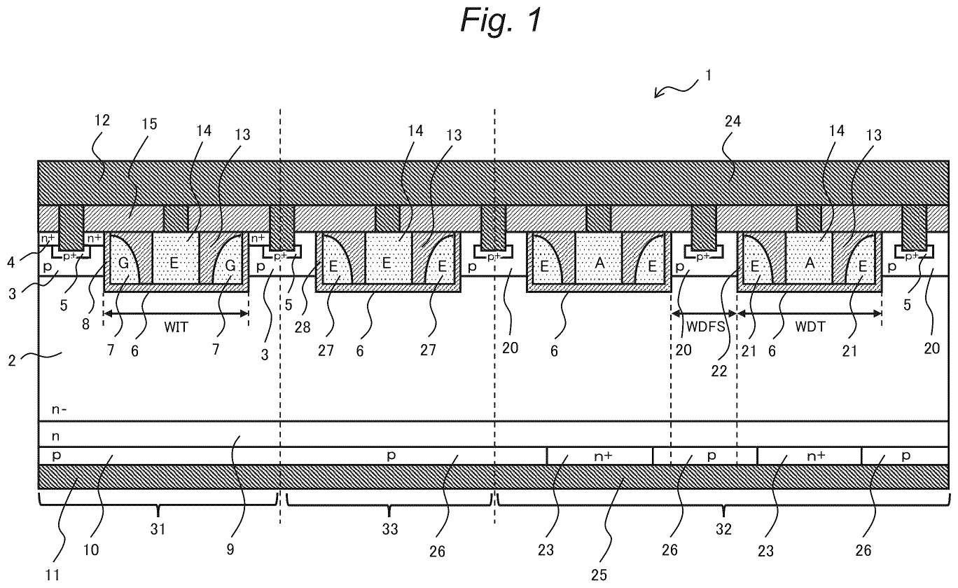

FIG. 1 is a cross-sectional view of a semiconductor device of a first embodiment.

This embodiment will be described by taking, as an example, the case where a first conductivity type is an n type, and a second conductivity type is a p type. In this case, a first semiconductor layer 20 of a diode region 32 described later becomes an anode layer, and a second semiconductor layer 23 of the diode region 32 becomes a cathode layer. It should be noted that the first conductivity type may be the p type, and the second conductivity type may be the n type, and in this case, the first semiconductor layer 20 becomes the cathode layer, and the second semiconductor layer 23 becomes the anode layer. In addition, the denotation as a hole for a carrier should be replaced with an electron.

A semiconductor device 1 of this embodiment is an RC-IGBT that has an IGBT region 31 and the diode region 32 in one chip.

An IGBT of the IGBT region 31 has a drift layer 2 of a first conductivity type, a body layer 3 of a second conductivity type provided closer to a front surface side than the drift layer 2, an emitter layer 4 of a first conductivity type provided closer to a front surface side than the body layer 3, a collector layer 10 of a second conductivity type provided closer to a back surface side than the drift layer 2, and a trench 6 (first trench) provided between two body layers 3 adjacent to each other.

Here, the trench 6 (first trench) of the IGBT region 31 is a wide trench, and unlike a narrow trench used for a typical trench gate, the trench 6 has, in its inside, two gate electrodes 7. Specifically, when, of the two body layers 3 adjacent to each other, one of them is a first body layer, and the other is a second body layer, the trench 6 has the gate electrode 7 (first gate electrode) provided via a gate insulation film 8 on the side wall on the first body layer side, the gate electrode 7 (second gate electrode) provided via the gate insulation film 8 on the side wall on the second body layer side, and an in-trench insulation film 13, and the first gate electrode and the second gate electrode are spaced via the in-trench insulation film 13 between the first gate electrode and the second gate electrode. Such a structure is also called a side gate structure, and has an advantage that the feedback capacity can be reduced since the opposite side of the channel region is covered by the thick in-trench insulation film 13, the opposite area of the gate and the collector becomes small. The gate electrode 7 is connected with the gate wiring and the gate pad in a portion, not illustrated, and a gate potential G is applied to the gate electrode 7.

The IGBT of the IGBT region 31 also has an emitter electrode 12 provided on the front surface side, an interlayer insulation film 15, a contact layer 5 of the second conductivity type having a higher density than the body layer 3, a field plate electrode 14 provided inside of the trench 6, a collector electrode 11 provided on the back surface side, and a buffer layer 9 of a first conductivity type provided between the drift layer 2 and the collector layer 10 and having a higher density than the drift layer 2. The emitter electrode 12 is connected to the body layer 3 via the contact hole provided in the interlayer insulation film 15 and the contact layer 5 provided in contact with the body layer 3. In addition, the emitter electrode 12 is also connected to the emitter layer 4. Further, the emitter electrode 12 is also connected to the field plate electrode 14, and applies an emitter potential E to the field plate electrode 14.

A diode of the diode region 32 is formed simultaneously with the IGBT of the IGBT region 31, and is thus similar in part to the IGBT of the IGBT region 31.

The diode of the diode region 32 has the drift layer 2, the first semiconductor layer 20 of the second conductivity type provided closer to a front surface side than the drift layer 2, the second semiconductor layer 23 of the first conductivity type provided closer to a back surface side than the drift layer 2, and the trench 6 (second trench) provided between two first semiconductor layers 20 adjacent to each other.

The trench 6 (second trench) of the diode region 32 is also a wide trench like the trench 6 (first trench) of the IGBT region 31. When one of the two first semiconductor layers 20 adjacent to each other is a primary first semiconductor layer, and the other is a secondary first semiconductor layer, the second trench has a diode region trench electrode 21 (first diode region trench electrode) formed via a diode region trench insulation film 22 on the side wall on the primary first semiconductor layer side, the diode region trench electrode 21 (second diode region trench electrode) formed via the diode region trench insulation film 22 on the side wall on the secondary first semiconductor layer side, and the in-trench insulation film 13, and the first diode region trench electrode and the second diode region trench electrode are spaced via the in-trench insulation film 13 between the first diode region trench electrode and the second diode region trench electrode. The diode region trench electrode 21 is connected with the emitter electrode 12 in a portion, not illustrated, and the emitter potential E is applied to the diode region trench electrode 21. It should be noted that the present invention is not limited to this, and the gate potential G may be applied to the diode region trench electrode 21.

The diode of the diode region 32 also has a first electrode 24 provided on the front surface side, the interlayer insulation film 15, the contact layer 5 of the second conductivity type having a higher density than the first semiconductor layer 20, the field plate electrode 14 provided inside of the trench 6, a second electrode 25 provided on the back surface side, and the buffer layer 9 of the first conductivity type provided between the drift layer 2 and the second semiconductor layer 23 and having a higher density than the drift layer 2. The first electrode 24 is formed integrally with the emitter electrode 12, and is connected to the emitter electrode 12. Therefore, in this embodiment, the first electrode 24 that is an anode electrode has an anode potential A, and has the same potential as the emitter potential E. In addition, the second electrode 25 is formed integrally with the collector electrode 11, and is connected to the collector electrode 11. The first electrode 24 is connected to the first semiconductor layer 20 via the contact hole provided in the interlayer insulation film 15 and the contact layer 5 provided in contact with the first semiconductor layer 20. In addition, the first electrode 24 is also connected to the field plate electrode 14, and applies the anode potential A to the field plate electrode 14.

According to the structure of this embodiment, since the trench 6 (second trench) of the diode region 32 is made to be a wide trench, a diode region trench width WDT can be increased, so that the total area of the first semiconductor layer 20 can be made small. Therefore, the amount of the holes that are the carriers injected from the first semiconductor layer 20 on the front surface side at the time of diode conduction can be reduced (lowered injection), and the amount of the holes accumulated is reduced, so that a recovery current generated at the time of diode recovery is also reduced, thereby being capable of reducing a recovery loss. In addition, due to the wide trench, a large number of fine trenches are not required to be provided in order to reduce the total area of the first semiconductor layer 20, so that the influence of the limit of the fine processing of the trench is less likely to be received. It should be noted that although, to make the total area of the first semiconductor layer 20 smaller, a first semiconductor layer width WDFS can also be made smaller than the diode region trench width WDT, the present invention is not limited to this. In addition, although this embodiment exemplifies that the diode region trench width WDT is equal to an IGBT region trench width WIT, the present invention is not limited to this.

Further, in the semiconductor device 1 of this embodiment, the diode region 32 has a carrier discharge layer 26 of a second conductivity type provided closer to a back surface side than the drift layer 2, and the second semiconductor layer 23 and the carrier discharge layer 26 are alternately disposed. With this, the hole that is the carrier accumulated at the time of the diode conduction can be discharged from the carrier discharge layer 26, and the amount of the carriers accumulated can be reduced, so that the recovery current generated at the time of the diode recovery is also reduced, thereby being capable of further reducing the recovery loss.

In this way, in the semiconductor device 1 of this embodiment, the trench 6 (second trench) of the diode region 32 is made to be a wide trench, and the carrier discharge layer 26 is provided on the back surface side, so that the recovery loss can be effectively reduced.

The carrier discharge layer 26 is desirably provided at a position overlapped with the first semiconductor layer 20. With this, the first semiconductor layer 20 and the second semiconductor layer 23 are not opposite, so that the hole that is the carrier is less likely to be injected from the first semiconductor layer 20 at the time of the diode conduction, and the amount of the carriers injected can be reduced. It should be noted that to further reduce the amount of the carriers injected, the entire first semiconductor layer 20 is desirably overlapped with the carrier discharge layer 26, but the present invention is not limited to this.

In addition, like the semiconductor device 1 of this embodiment, desirably, a boundary region 33 is provided between the IGBT region 31 and the diode region 32, and the boundary region 33 has the carrier discharge layer 26. Here, desirably, the boundary region 33 has the trench 6 (third trench) of the boundary region 33, and the carrier discharge layer 26 is provided on the entire boundary region 33.

Since the recovery current is likely to be concentrated in the boundary region 33 at the time of the diode recovery, providing the carrier discharge layer 26 suppresses the carrier accumulation, and the reduction in the recovery current can suppress breakage caused due to the concentration of the recovery current, and can reduce the recovery loss.

It should be noted that the structure in the boundary region 33 is similar to the structure in the IGBT region 31 and the structure in the diode region 32. In the boundary region 33, the emitter layer 4 and the second semiconductor layer 23 are not formed. In addition, the trench 6 (third trench) of the boundary region 33 has a boundary region trench electrode 27, a boundary region trench insulation film 28, the in-trench insulation film 13, and the field plate electrode 14, and the emitter potential E is applied to the boundary region trench electrode 27 and the field plate electrode 14, but the present invention is not limited to this.

In this embodiment, the impurity density has been described by using the example in which the drift layer 2 is n− having a low density, the emitter layer 4 is n+ having a high density, the contact layer 5 is p+ having a high density, the second semiconductor layer 23 is n+ having a high density, and other than that is n or p, but the present invention is not limited to this, and can be changed, as needed, in the range in which the operation intended by this embodiment is enabled.

### Second Embodiment

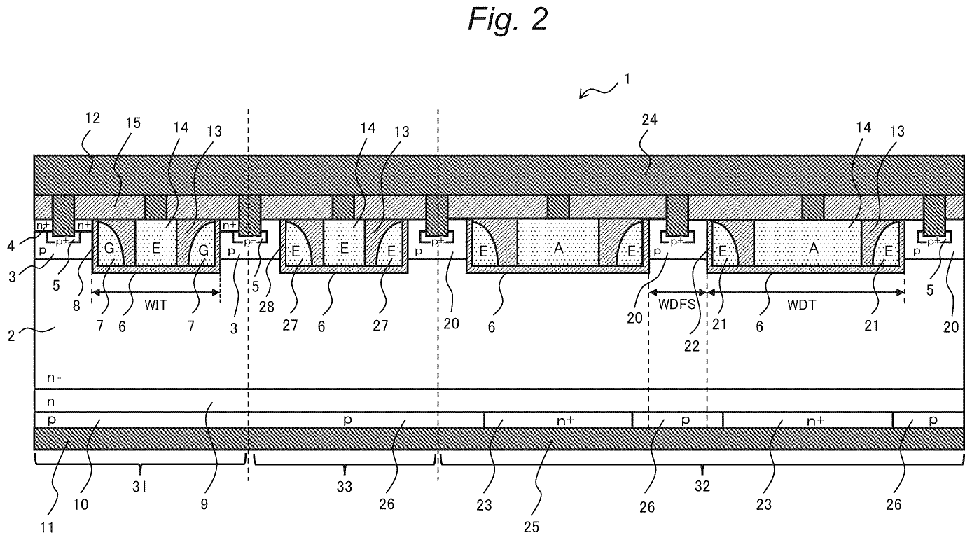

FIG. 2 is a cross-sectional view of a semiconductor device of a second embodiment.

The second embodiment is a modification example of the first embodiment, and is different from the first embodiment in that the width of the first trench and the width of the second trench are different.

This embodiment exemplifies that the diode region trench width WDT is larger than the IGBT region trench width WIT, but the present invention is not limited to this.

According to this embodiment, since the diode region trench width WDT and the IGBT region trench width WIT can be independently regulated, the characteristic of the IGBT region 31, the characteristic of the diode region 32, in particular, the recovery characteristic of the diode region 32 can be independently regulated.

The embodiments of the present invention have been described above, but the present invention is not limited to the configurations described in the embodiments, and various changes can be made within the scope of the technical idea of the present invention. In addition, portions or all of the configurations described in the respective embodiments may be combined and applied.

### REFERENCE SIGNS LIST

1: semiconductor device
2: drift layer
3: body layer
4: emitter layer
5: contact layer
6: trench
7: gate electrode
8: gate insulation film
9: buffer layer
10: collector layer
11: collector electrode
12: emitter electrode
13: in-trench insulation film
14: field plate electrode
15: interlayer insulation film
20: first semiconductor layer
21: diode region trench electrode
22: diode region trench insulation film
23: second semiconductor layer
24: first electrode
25: second electrode
26: carrier discharge layer
27: boundary region trench electrode
28: boundary region trench insulation film
31: IGBT region
32: diode region
33: boundary region
WIT: IGBT region trench width
WDT: diode region trench width
WDFS: first semiconductor layer width
G: gate potential
E: emitter potential
A: anode potential

1. A semiconductor device comprising an IGBT region and a diode region in one chip, wherein
an IGBT of the IGBT region has a drift layer of a first conductivity type, a first body layer of a second conductivity type and a second body layer of a second conductivity type which are provided closer to a front surface side than the drift layer, an emitter layer of a first conductivity type provided closer to a front surface side than the first body layer and the second body layer, a collector layer of a second conductivity type provided closer to a back surface side than the drift layer, and a first trench provided between the first body layer and the second body layer,
the first trench has a first gate electrode provided via a gate insulation film on a side wall of the first body layer side, a second gate electrode provided via a gate insulation film on a side wall of the second body layer side, and an in-trench insulation film, and the first gate electrode and the second gate electrode are spaced via the in-trench insulation film between the first gate electrode and the second gate electrode,
a diode of the diode region has the drift layer, a primary first semiconductor layer of a second conductivity type and a secondary first semiconductor layer of a second conductivity type which are provided closer to a front surface side than the drift layer, a second semiconductor layer of a first conductivity type provided closer to a back surface side than the drift layer, and a second trench provided between the primary first semiconductor layer and the secondary first semiconductor layer,
the second trench has a first diode region trench electrode formed via a diode region trench insulation film on a side wall of the primary first semiconductor layer side, a second diode region trench electrode formed via a diode region trench insulation film on a side wall of the secondary first semiconductor layer side, and the in-trench insulation film, and the first diode region trench electrode and the second diode region trench electrode are spaced via the in-trench insulation film between the first diode region trench electrode and the second diode region trench electrode, and
the diode region has a carrier discharge layer of a second conductivity type provided closer to a back surface side than the drift layer, and the second semiconductor layer and the carrier discharge layer are alternately disposed.

2. The semiconductor device according to claim 1, wherein
the primary first semiconductor layer and the secondary first semiconductor layer are overlapped with the carrier discharge layer.

3. The semiconductor device according to claim 1, wherein
a width of the second trench is larger than a width of the primary first semiconductor layer and a width of the secondary first semiconductor layer.

4. The semiconductor device according to claim 1, wherein
a width of the first trench and a width of the second trench are different.

5. The semiconductor device according to claim 1, wherein
the semiconductor device has a boundary region between the IGBT region and the diode region, and
the boundary region has the carrier discharge layer.

6. The semiconductor device according to claim 5, wherein
the boundary region has a third trench, and the carrier discharge layer is provided on the entire boundary region.
